(19) United States
(12) Patent Application Publication
(10) Pub. No.: US 2005/0078024 A1
(43) Pub. Date: Apr. 14, 2005

(54) Digital current limiter

(75) Inventor: James B. Harrington, Seminole, FL (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 10/961,339

(22) Filed: Oct. 8, 2004

Related U.S. Application Data
(60) Provisional application No. 60/510,066, filed on Oct. 9, 2003.

(51) Int. Cl. H03M 1/12

(52) U.S. Cl. 341/155

(57) ABSTRACT

A digital current limiter is provided. The digital current limiter includes a microprocessor that is capable of monitoring and controlling multiple current flows concurrently. The microprocessor can be programmed with various current limits and current control functions than can be set and modified in software. In addition, by including a serial communication interface, the current limits and current control functions of the digital current limiter can be modified remotely.

### PRIORITY

The present patent application claims priority under 35 U.S.C. § 119(e) to the U.S. Provisional Patent Application No. 60/510,066, filed on Oct. 9, 2003, entitled “Digital Current Limiter,” to Harrington, the full disclosure of which is incorporated herein by reference.

### BACKGROUND

1. Field of Invention

The present invention relates to electrical current control and, more particularly, to digital current control, and extends to digital power control because of the ability to digitally control current.

2. Description of Related Art

For many applications, it is important to control the current flow in a circuit using a current limiter. For example, it may be desirable to limit current flow from a power supply to an electrical appliance to prevent damage to the appliance by current overload. Traditionally, current limiting is accomplished with analog circuits. However, analog current limiters are often complex and inflexible. To modify functionalities of an analog current limiter may involve modifying circuit design and changing out components. In addition, analog current limiters are also typically designed for controlling a single current flow at a time. Further, implementing logic control functionality with analog current limiters is often difficult.

In today's world, however, electrical system functionality is very dynamic. New functions are often being added to existing systems and equipment. This trend is seen from portable-device applications, such as cell phones and PDAs, to high end navigation systems for airliners and military aircraft. The new functions can often cause higher current demands that, in turn, may require providing new current limits to protect the existing electrical systems from damage due to over-current conditions. Unfortunately, existing analog current limiting solutions typically require parts change-out to provide such new current limit levels. A need therefore exists for a more flexible current limiting solution.

Further, many of the new products today rely on battery power. As the battery nears the end of life, digital power control can be used to extend the time left before the battery must be changed. It would be desirable to provide digital power control by monitoring the input voltage and digitally limiting the current to necessary circuitry to shed less useful functions.

### SUMMARY

In one embodiment of the present invention, the digital current limiter includes one or more switches that are each serially coupled to a respective current sensing circuit. The respective current sensing circuit functions to sense current flowing at the respective switch and responsively produce an indication of a magnitude of the current. The current sensing circuit is then electrically coupled to a digital controller, which, in one illustrative embodiment, is a microprocessor.

The digital controller receives the indication of the magnitude of the current and, in turn, controls the respective switch based on the magnitude of the current. Advantageously, the digital controller can monitor and control multiple current flows concurrently. In addition, various current limits and other functionality can easily be set and modified in software.

This as well as other aspects of the present invention will become apparent to those of ordinary skill in the art by reading the following detailed description, with appropriate reference to the accompanying drawings.

### BRIEF DESCRIPTION OF THE DRAWINGS

Presently disclosed embodiments are described below in conjunction with the appended drawing figures, wherein like reference numerals refer to like elements in the various figures, and wherein:

FIG. 1 illustrates a block diagram of a digital current limiter in accordance with one embodiment of the invention;

FIG. 2 illustrates an example of a circuit diagram of the embodiment of the digital current limiter of FIG. 1;

FIG. 3 illustrates a flow diagram of a circuit-breaker algorithm;

FIG. 4 illustrates a block diagram of one embodiment of a system for performing predictive health maintenance;

FIG. 5 illustrates an embodiment for a load shedding application;

FIG. 6 illustrates an embodiment of a load control carried out by a master controller;

FIG. 7 illustrates one embodiment of the circuit diagram of FIG. 2 arranged for a power switchover operation between two inputs.

### DETAILED DESCRIPTION

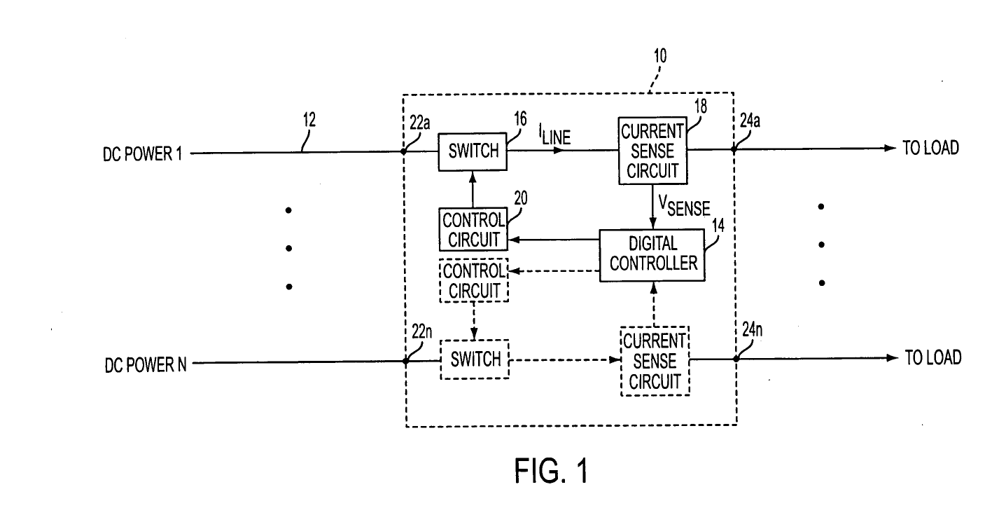

1. Overview FIG. 1 is a simplified block diagram of a digital current limiter 10 in accordance with one disclosed embodiment of the present invention. As illustrated in FIG. 1, digital current limiter 10 includes one or more power inputs 22a-n and corresponding outputs 24a-n. Each of the power inputs 22a-n can be connected to a respective DC input power line, such as an input power line 12. As further shown in FIG. 1, digital current limiter 10 includes a digital controller 14 that can concurrently monitor and control current flowing from each of the one or more inputs 22a-n to the corresponding output 24 via a respective (i) switch (e.g., a switch 16), (ii) current-sense circuit (e.g., a current-sense circuit 18), and (iii) control circuit (e.g., a control circuit 20).

In operation, when switch 16 is “on” (i.e., closed), input power line 12 is electrically coupled to a load on output 24a. Resulting current I_{LINE} flows to the load through current-sense circuit 18, which produces a voltage V_{SENSE} that is directly proportional to the magnitude of the current I_{LINE}. In other words, as I_{LINE} increases, V_{SENSE} increases proportionally and vice versa. V_{SENSE} is then provided as an input to digital controller 14 that may be programmed to compare the value of V_{SENSE} (e.g., a scaled or current-converted form thereof) to predetermined current limit(s) (e.g., over-current and/or other limits) to evaluate current conditions and execute current control functions as needed. In particular, digital controller 14 can control the flow of I_{LINE} to the load via switch 16 by signaling to control circuit 20 to turn switch 16 “on” and “off”. As one example, upon detecting that the level of I_{LINE} (proportional to V_{SENSE}) indicates a severe over-current condition (e.g., due to a short circuit in the load at output 24a), digital controller 14 may be programmed to send a control signal to circuit 20. In response to the control signal from digital controller 14, the control circuit can provide an input signal to switch 16 to turn the switch 16 “off”, thus preventing the current from flowing to the load.

In situations where the load is a DC to DC converter, a better indication of an overload may be input power. A DC to DC converter is a constant power device; as the input voltage goes down, the input current goes up. In analog current limit circuits only the worst case current limit can be used. In a digital current limiter, the input voltage can also be monitored to evaluate the power consumed by the load. When the load short-circuits, the input power will increase regardless of voltage levels or current limits. A digital current limiter monitoring the input voltage can detect an out of specification condition more accurately than an analog current limiter.

2. Circuit Diagram

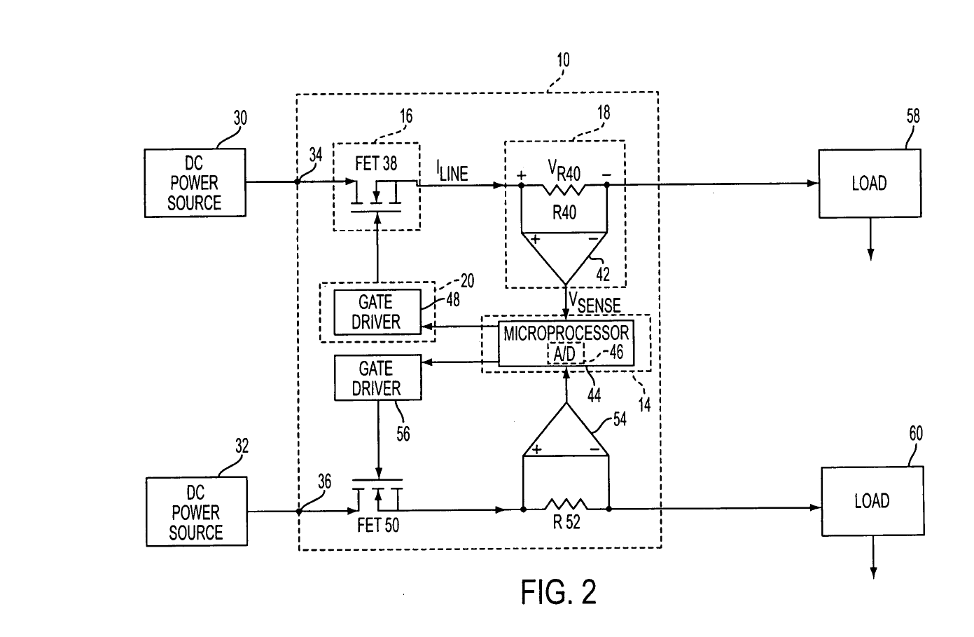

FIG. 2 illustrates in greater detail one possible circuit implementation of representative digital current limiter 10 of FIG. 1. By way of example, FIG. 2 illustrates digital current limiter 10 as having two power inputs 34 and 36 for coupling to respective DC power sources 30 and 32, each of which can take various forms, including a power supply, a voltage regulator, or a battery. It should be understood, however, that digital current limiter 10 may have a greater or fewer number of inputs than shown in FIG. 2. Further note that digital current limiter 10 may control fewer current flows than given power inputs, and some of the inputs may be left unused and/or used at a later time if additional current control is needed. Alternatively, current limiter 10 may control more current flows than the given number of power inputs by branching the power input through multiple switches.

In the embodiment shown in FIG. 2, switch 16 (of FIG. 1) includes a Field-Effect Transistor (FET) 38, such as an enhancement-type Metal Oxide Semiconductor FET (MOSFET) commonly used for signal switching. Alternatively, a Bipolar Junction Transistor (BJT), a power MOSFET (e.g., a DMOS transistor suitable for high-power applications), an Insulated Gate Bipolar Transistor (IGBT), a relay, and/or another device(s) could be used instead.

A FET conventionally has a gate, a source, a drain, and body (or substrate) terminals, and can be controlled (i.e., turned “on” or “off”) by a voltage that is applied at a gate of the transistor. In particular, when a voltage V_{GS} (also known as a “gate drive” voltage) of sufficient magnitude (typically greater than a given threshold voltage V_{T} for an N-channel FET and less than a given threshold voltage V_{T} for a P-channel FET) is applied between a gate and a source of a FET in an “off” state, a conductive channel is induced within the FET such that a current flows between a drain and the source, turning the FET “on”. Similarly, by adjusting V_{GS} accordingly (i.e., typically by dropping V_{GS} below a given V_{T} for an N-channel FET and increasing V_{GS} above a given V_{T} for a P-channel FET), the FET can be turned back “off”. When “off”, the FET is placed in a high-impedance state and is thus substantially non-conductive.

As further shown in the embodiment of FIG. 2, current-sense circuit 18 comprises a current-sense resistor R40 and a differential amplifier 42. In practice, as the current I_{LINE} flows through current-sense resistor 40, a voltage V_{R40} develops across resistor R40. As noted above, the voltage drop across sense resistor R40 will be directly proportional to the current flowing through the sense resistor R40. Preferably, the value of resistor R40 is selected to be substantially small (e.g., 0.033 ohm or less (e.g., values as low as 0.001 ohm are available)) such that an output voltage presented to a load 58 is not reduced excessively. Note that when selecting a suitable value/type of current-sense resistor R40, maximum resistor power rating and/or power derating over temperature are preferably taken into consideration.

V_{R40} is provided as an input to differential amplifier 42, which can scale V_{R40} to a higher value to produce V_{SENSE}. In a preferred embodiment, differential amplifier 42 is an instrumentation amplifier. It will be recognized that various suitable instrumentation amplifier ICs are readily available. The benefits of using an instrumentation amplifier IC include easy gain adjustments (e.g., a desired gain can typically be set with a single external resistor), wide gain ranges (e.g., 1-1000), and low internal offset voltages for a high degree of precision. If desired, any internal offset voltages can typically be further nulled out by adding one or more adjustable resistors (e.g., pot resistor(s)). An advantage of a digital control system is that a digital controller, such as digital controller 14, can also be used to subtract off any known offset(s) as a part of control algorithm(s).

In the illustrated embodiment, digital controller 14 can be a microprocessor/microcontroller, such as a microprocessor 44. It will be appreciated that, depending on design needs (e.g., number data inputs/outputs required, etc.), various digital microprocessors/microcontrollers known in the art could be used. Preferably, microprocessor 44 will include a built-in analog-to-digital (A/D) converter 46 for converting an analog value of V_{SENSE} to a digital value that can be processed by microprocessor 44. Alternatively, the A/D converter 46 may be a distinct logic part. Note that an optimum input voltage level of V_{SENSE} provided to A/D converter 46 can be achieved by adjusting the gain of differential amplifier 42.

As further depicted in FIG. 2, microprocessor 44 can be coupled to a gate driver 48, which may be used to implement control circuit 20. A typical gate drive circuit provides necessary gate voltages for switching a FET (e.g., a MOSFET) “on” and “off” by controlling its drive voltage V_{GS} as discussed above. Gate driver 48 can take different forms, including a discrete gate drive circuit or a gate driver IC. Because most gate driver ICs can be directly controlled from microprocessor logic circuits (e.g., by low and high logic signal (e.g., 0V_{DC} and 5V_{DC}), a gate driver IC is a preferred form of gate drive circuit 48.

A FET 50, a current-sense resistor R52, a differential amplifier 54, and a gate driver 56 shown in FIG. 2 in connection with the second DC power source 32 and a load 60 may be the same as corresponding FET 38, current-sense resistor R40, differential amplifier 42, and gate driver 48 or different (in form and/or value). Also, note that each of loads 58 and 60 generally shown in FIG. 2 may take various forms, including a single circuit board/module, a combination of circuit boards/modules, a subcircuit, etc. Many variations are possible.

In one alternative embodiment of digital current limiter 10, current-sense resistor R40, differential amplifier 42, and A/D converter 46 can be replaced by a current sensing IC, such as the IR2171 part available from International Rectifier. The IR2171 is a monolithic IC that measures a floating differential voltage across a current-sense resistor and converts it to a digital output that can be referenced to a microprocessor input (e.g., an input to microprocessor 44). Other alternatives for implementing the front end of digital current limiter 10 are possible as well.

3. Current Control

One of the advantages of using digital current limiter 10 over analog current-limiting circuits is the ease of implementing various current control methods without a necessity for changing out parts. In particular, a variety of current control algorithms (including any desired current limit(s)) can be implemented in software as a set of program logic (e.g., machine language instructions) executable by a digital controller, such as microprocessor 44. In one example, as generally noted above, digital controller 14 may be programmed to detect a heavy over-current condition (e.g., by comparing a level of a measured current to a predetermined current limit level and determining that the measured current level exceeds this limit) and may responsively signal to control circuit 20 to turn off switch 16.

In another example, digital controller 14 may be programmed to limit the current flow by pulsing switch 16 “on” and “off” for given periods of time. For example, during an over-current event, digital controller 14 may turn switch 16 “off” for some time and then turn the switch back “on” briefly to sample the current. If the over-current condition has been removed, switch 16 may remain “on”. Otherwise, digital controller 14 may turn the switch “off” again and repeat the cycle. This method of current limiting can lower an average current flowing to a load (typically at low over-current conditions when a ratio of “on” time T_{ON} of switch 16 to “off” time T_{OFF} of switch 16 (also known as a “duty cycle”) can be kept fairly constant) and decrease power dissipation within a DC power source, such as a power supply. In particular, in this method, excess heat due to an over-current event (that may be caused by an overload on a power supply output) will typically last for only a short period of time during which switch 16 is “on”. Further, digital controller 14 may execute an algorithm to automatically adjust durations of T_{ON} and T_{OFF} of switch 16 based on a severity of a given over-current condition. For instance, digital controller 14 may automatically adjust the durations of T_{ON} and T_{OFF} based on a peak value of a measured overcurrent. As the peak value of the measured overcurrent increases, the duration of T_{ON} may be automatically decreased while the duration of T_{OFF} may be increased.

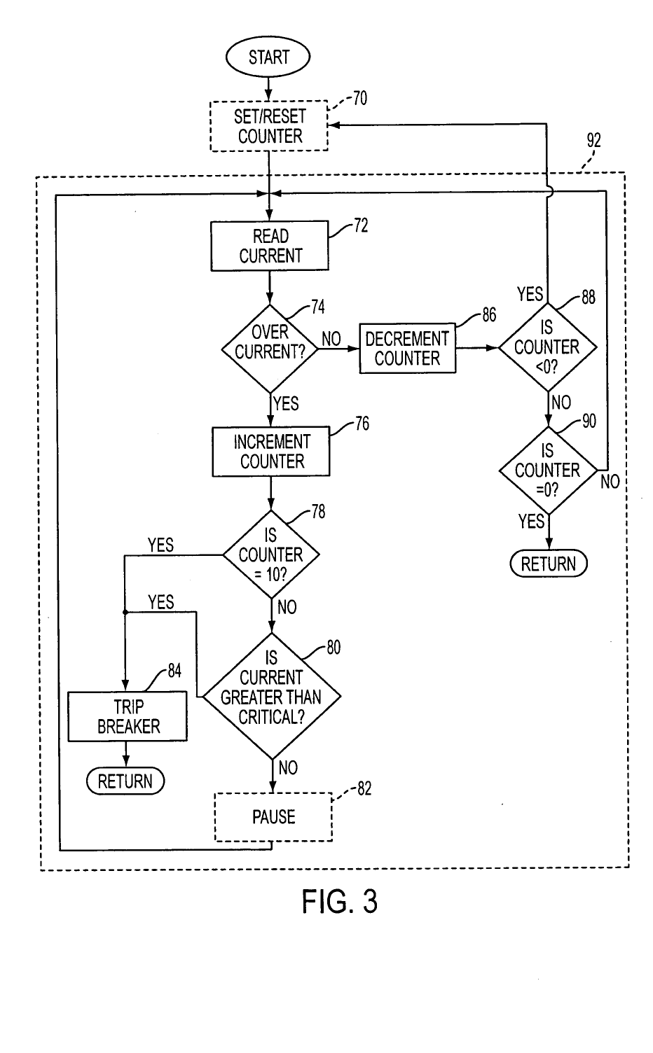

FIG. 3 further illustrates an example of an algorithm for carrying out a circuit breaker operation according to one illustrative embodiment. Advantageously, the illustrated algorithm of FIG. 3 provides for a two-level current trip that is normally employed by traditional circuit breakers, but that can be complex to reproduce with analog circuitry. The two-level current trip has a normal trip when an over-current condition exists for a given length of time or an instant trip when a critical current level is exceeded.

Referring now to FIG. 3, at block 70 outside a main control loop 92, a counter is set or reset to 0. Note that the following description of FIG. 3 does not assume that the starting counter value at block 72 is necessarily 0, and various scenarios are discussed.

Starting at block 72, digital controller 14 reads a measure of a current level, which can be supplied via an A/D channel on digital controller 14 (and that can be directly read as a digitized voltage value or further converted to an actual current value). At decision block 74, digital controller 14 determines if a measured current is an overcurrent. For instance, the digital controller may compare the measured current level to a predetermined over-current limit level that specifies a threshold current level above which a current is considered to be an overcurrent. If the current level exceeds this threshold, the digital controller may conclude that the measured current is an overcurrent and, at block 76, increment the counter. If, however, the digital controller determines that the measured current level is not at a level indicating an overcurrent event, the digital controller then decrements the counter as shown in block 86.

Assuming that an over-current event occurs, at block 78, the digital controller compares the value of the counter to a predetermined counter limit, which in this example, is set to 10. The predetermined limit of the counter can correspond to a number of current measure readings (every millisecond, for instance) needed to conclude that an over-current condition exists, and can be arbitrarily set to any desired number. Typically, repeating current measurement readings several times (and thus setting the counter value to a number greater than one) may help to evaluate the criticality of an over-current condition and to rule out “false” over-current events that may be caused by current transients due to noise, for instance.

In one example, if the digital controller determines that the counter value is greater than the preset value of 10, at block 84, the digital controller executes a tripping command, such as by signaling to control circuit 20 to turn switch 16 off, and may return to block 70 at which the counter is reset to 0. Note that after executing the tripping command, the digital controller may be configured to generate a “power fault” indication (e.g., via status bits out of the controller) and may not resume current processing until such fault is cleared.

In another example, if the digital controller determines that the counter is less than 10 (i.e., not equal to 10), at block 80, the digital controller then compares the current level to a critical-current limit level and determines if the current level exceeds the critical-current limit level. If the current level is not above the critical-current limit level, at block 82, the digital controller may pause for a given time interval, and/or may return back to executing main control loop 92 starting at block 72. However, if the current level exceeds the critical-current limit level, the controller proceeds to block 84 and executes a tripping command, such as by signaling to control circuit 20 to turn switch 16 off, and may return to block 70 at which the counter is reset to 0. Again, after executing the tripping command, the digital controller may be configured to generate a “power fault” indication, and may not resume current processing until such fault is cleared. Additionally, since the critical-current limit level has been exceeded, a “critical power fault” indication may be issued causing a different set of actions by the controller.

As noted above, at block 74, digital controller 14 may determine that a measured current is not an overcurrent, and, at block 86, decrement the counter. In this case, current processing then advances to decision block 88 at which the digital controller determines if the counter value is less than 0. Note that the counter value may become negative if its starting value is 0 (e.g., after the digital controller executes a tripping command and resets the counter back to 0 or right at the beginning of execution of the circuit-breaker algorithm). As shown in FIG. 3, if the counter is determined to be negative at block 88, the digital controller returns to block 70 and resets the counter back to 0. Current processing may then advance to block 72.

If, at block 88, the digital controller determines that the counter value is not less than 0, the digital controller executes the next processing step at block 90 to determine whether the counter value is equal to zero. If the counter value is 0, the digital controller returns back from block 90. If the counter value is greater than 0, the digital controller resumes execution of main control loop 92 starting at block 72.

Note that in executing the algorithm of FIG. 3 (or any other current control function(s)) upon start-up of an electric system (e.g., during an initial turn-on of a power supply), digital controller 14 may be programmed with an inrush delay interval that will cause the controller to delay current processing temporarily and/or check for an indication of presence of high inrush currents typically associated with the start-up. For example, when a power supply is first powered up, internal capacitors are discharged and act like short circuits, producing immediate input surge currents. Advantageously, various inrush control methods (e.g., setting inrush-current limit levels) can be easily implemented in software and programmed into the digital controller.

Similarly, when new functions (and thus new circuitry) are added to the existing equipment, causing the equipment to draw higher current(s), current control function(s) and/or current limit(s) may be modified accordingly in software and programmed into the digital controller.

Further, it should be understood that, in applications in which digital current limiter 10 is used for concurrently monitoring and controlling multiple current flows, any current-control functions/current limits implemented by the digital current limiter may be set accordingly (if necessary) for each individual current flow controlled by the current limiter. For instance, if the digital current limiter is used to monitor and control current levels on multiple supply voltage lines, current levels on individual supply voltage lines may vary based on the supply voltage level, supply load, and/or other factors. Therefore, current limits (e.g., set based on rated supply current) applicable to a current flow on one supply voltage line may not be the same as those for other supply voltage line(s). Advantageously, given the flexibility of software control, representative digital current limiter 10 (or, more particularly, digital controller 14 (e.g. example microprocessor 44 of FIG. 2)) can be programmed accordingly depending on the application.

In this regard, in one preferred embodiment, digital controller 14 will include communication interface(s) (e.g., designated serial port(s) and/or other hardware) to allow for remote modification and/or addition of current-control functions and/or current limit(s). Advantageously, the operation of the digital current limiter may be controlled or adjusted remotely based on needs of a given application, operating conditions (e.g., emergency conditions in which dynamic current control may be critical, an operating environment (e.g., temperature conditions, noise, etc.), operating mode (e.g., a power-up), and/or other factors.

For instance, changes in load conditions (e.g., during system operation) may increase system current demands. This, in turn, may necessitate changes to existing current limits in order to protect the system from potential over-current damage due to an overload. With the benefit of the present embodiment, remote modifications to the existing current limits in such situations are possible.

4. Example Applications

According to the disclosed embodiment, in addition to providing current monitoring and digital control, representative digital current limiter 10 may also be used for a variety of other applications.

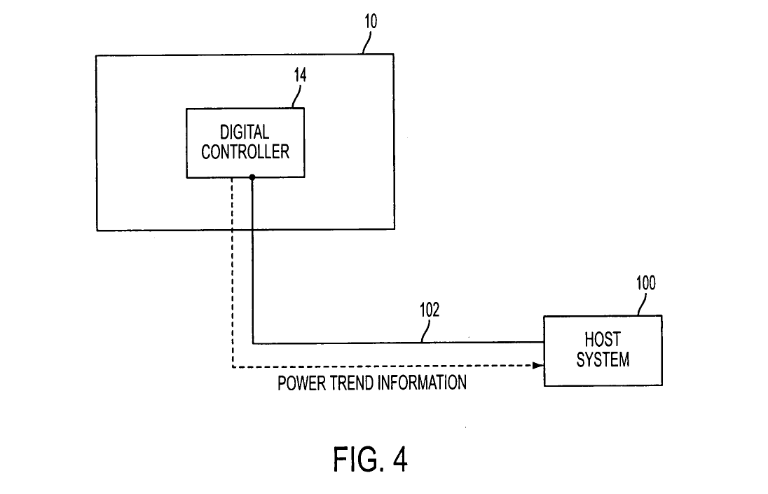

For instance, in the preferred embodiment in which digital current limiter 10 includes a remote communication interface, such as a serial port or a wireless link, digital current limiter 10 may communicate with a host system (e.g., a main host computer) for performing so-called “predictive health maintenance” in which health of a system is monitored to predict any potential failures and to take protective measures to prevent these failures. FIG. 4 illustrates an example of an arrangement in which digital controller 14 communicates over a serial channel 102 with a host system 100. In this example arrangement, digital controller 14 can identify power trends to host system 100 for an additional review.

As an example, digital current limier 10 can send to host system 100 information regarding any over-current events (e.g., due to shorts, overloads, and/or ground faults) that have occurred in an electric system. In this regard, the digital current limiter can additionally provide host system 100 with information in which areas of the electric system these over-current events occurred. Digital current limiter 10 can also send to host system 100 current measurements collected periodically and/or other type of information. This information may, in turn, be reviewed by host system 100 to identify any potential problems with the electric system. This capability could be very useful in safety critical applications, such as avionics applications. In one instance, based on the review of information received from digital controller 14, as a safety measure, host system 100 could automatically initiate a switchover to backup equipment to avoid potential equipment failures.

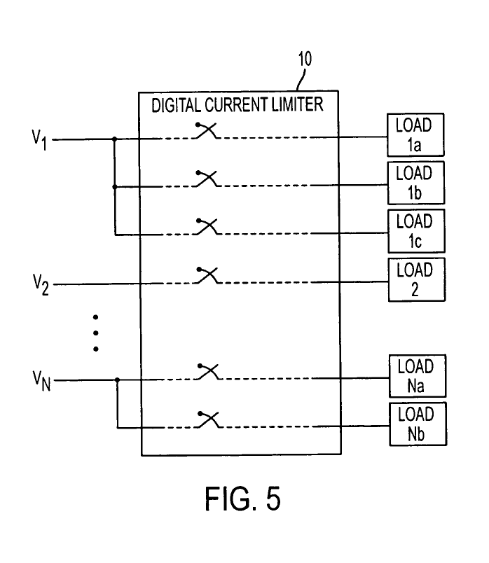

FIG. 5 illustrates one embodiment in which digital current limiter 10 could perform load shedding functions. As known in the art, the concept of load shedding relates to “shedding” loads from power lines to relieve overload conditions. As shown in FIG. 5, digital current limiter 10 may monitor multiple voltage lines V₁-V_{N} coupled to respective loads 1a-Nx via the digital current limiter. Whenever digital controller 14 (not shown) detects an overload condition on any voltage line V₁-V_{N}, the digital controller could open a respective switch on any overloaded line to “shed” a load connected to that line. Note that an overload will typically cause an increase in current, which in turn causes line voltage to drop proportionally. As such, digital controller 14 may detect an overload condition by detecting a corresponding overcurrent due to an overload. The digital controller could then enunciate a “power fault” condition and initiate any necessary power backup.

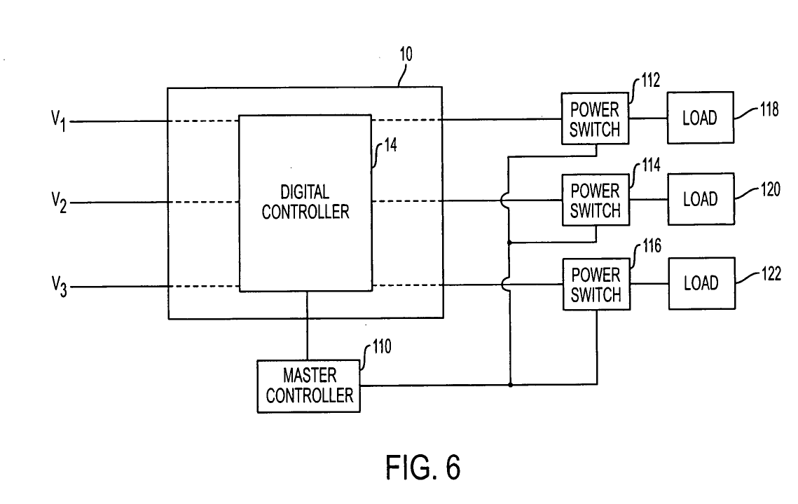

FIG. 6 illustrates another embodiment in which digital controller 14 is coupled through a serial interface to a master controller 110, which controls multiple power switches 112-116 connected to respective loads 118-122. Note that master controller 110 and each of the power switches could be interconnected through serial peripheral interface (SPI) lines. In this particular embodiment, master controller 110 may communicate with digital controller 14 to obtain power information related to each of the loads (e.g., current draw of each load, etc.) and can control power to each of the loads by turning the respective load power switch on or off as needed. This functionality could be useful in managing power drain of battery sources, such as those used on an aircraft. As an example, in aircraft applications, master controller 110 (e.g., on-board main computer) may be able to control power switches on various auxiliary systems to mange power consumption from one or more power sources. For example, while in-flight, various equipment, such as wheels and landing gears (among others), is typically not used and power can typically be turned off to this equipment while not being used. As another example, in a cell phone or a personal data assistant (PDA), the back light option can be prevented from coming on when the system it activated when a low battery indication has been detected. This type of digital power control will extend the usable life of the battery.

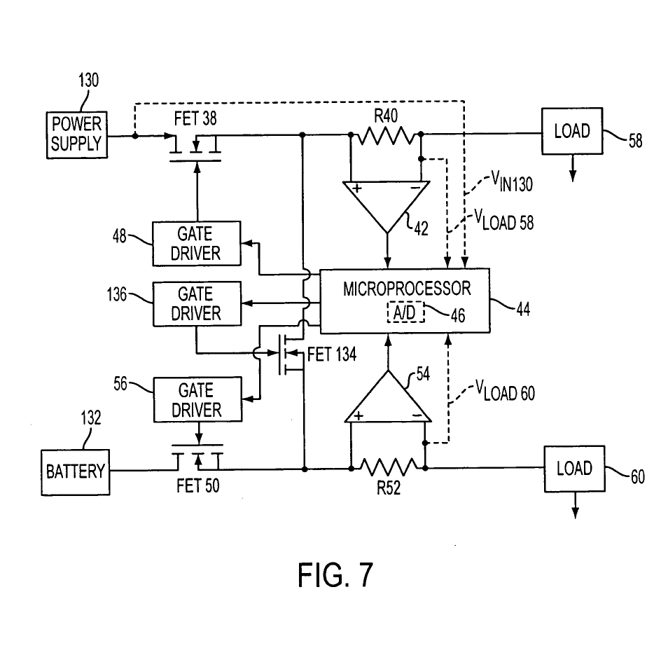

Lastly, FIG. 7 depicts a modified circuit of FIG. 2 to illustrate an embodiment in which loads 58 and 60 can be switched over from their primary power source (e.g., a power supply source 130) to a secondary power source (e.g., a battery source 132) if, for instance, voltage V_{IN130} on the primary power source drops below a given threshold level (e.g., <20 V). This operation may be especially beneficial in applications that require a certain level of input voltage in order to start up. The two power sources can be interconnected by a connection through FET 134 (controlled by a gate driver 136), although additional circuitry (e.g., diodes) not shown could be included to minimize coupling between the two power lines. Further, output load voltages V_{LOAD58} and V_{LOAD60} may be obtained by coupling respective single-ended inputs on microprocessor 44 to one of the floating voltage inputs on a respective differential amplifier, as shown in FIG. 7. Advantageously, V_{LOAD58} and V_{LOAD60} could also be used for calculating output power and utilizing these measurements in power limiting applications.

5. Conclusion

While particular embodiments have been described, persons of skill in the art will appreciate that variations may be made without departure from the scope and spirit of the invention. This true scope and spirit is defined by the appended claims, which may be interpreted in light of the foregoing.

1. A digital current limiter, comprising:
one or more switches, wherein each respective switch is serially coupled to a respective current sensing circuit, and wherein the respective current sensing circuit senses current flowing at the respective switch and responsively produces an indication of a magnitude of the current; and
a digital controller electrically coupled to the respective current sensing circuit, the digital controller configured to receive the indication of the magnitude of the current and control the respective switch according to the magnitude of the current.

2. The digital current limiter of claim 1 adapted for performing digital power control.

3. The digital current limiter of claim 1, wherein the one or more switches is a plurality of switches.

4. The digital current limiter of claim 3, wherein the digital controller concurrently controls each of the plurality of switches.

5. The digital current limiter of claim 1, wherein the digital controller controls the respective switch via a respective control circuit electrically coupled to the digital controller.

6. The digital current limiter of claim 5, wherein the respective control circuit is a gate drive circuit.

7. The digital current limiter of claim 5, wherein the digital controller generates control signals to the respective control circuit to turn the respective switch on or off based on the magnitude of the current.

8. The digital current limiter of claim 1, wherein the respective switch is a FET, a BJT, an IGBT, or a relay.

9. The digital current limiter of claim 1, wherein the indication of the magnitude of the current is an analog voltage directly proportional to the magnitude of the current, and wherein the digital controller includes an analog-to-digital converter to convert the analog voltage to a digital signal.

10. The digital current limiter of claim 1, wherein the respective current sensing circuit includes a current sense resistor and a differential amplifier, and wherein the differential amplifier is an instrumentation amplifier.

11. The digital current limiter of claim 1, wherein the digital controller is microprocessor or a microcontroller.

12. The digital current limiter of claim 1, wherein the digital controller compares the magnitude of the current to a predetermined current limit and causes the switch to switch to an on state or an off state based on whether the magnitude of the current exceeds the current limit.

13. The digital current limiter of claim 1, wherein the digital controller causes the switch to switch to an on state or an off state in a pulsing manner when the magnitude of the current exceeds the current limit.

14. The digital current limiter of claim 1, wherein the digital controller includes a communication interface.

15. The digital current limiter of claim 14, wherein the communication interface is a serial port.

16. The digital current limiter of claim 14, wherein the communication interface is a wireless link.

17. The digital current limiter of claim 12, wherein the digital controller includes a communication interface, and wherein the predetermined current limit can be modified remotely via the communication interface.

18. The digital current limiter of claim 14 adapted for use in an electric system, wherein the communication interface is serially connected to a host system, and wherein the digital controller provides the host system with information related to the electric system.

19. The digital current limiter of claim 18, wherein the host system reviews the information related to the electric system to determine a health status of the electric system.

20. The digital current limiter of claim 1, wherein the respective switch and the respective current sensing circuit are serially coupled between a power source and a load, and wherein the respective switch functions (i) to electrically couple the power source and the load when the switch is an on state and (ii) to electrically isolate the power source and the load when the switch is an off state.

21. The digital current limiter of claim 20, wherein the current flows via the respective switch when the switch is the on state, electrically coupling the power source and the load.

22. The digital current limiter of claim 20, wherein the power source is selected from the group consisting of (i) a power supply, (ii) a battery, and (iii) a voltage regulator.

23. The digital current limiter of claim 20, wherein when the digital controller determines that the magnitude of the current indicates an over-current condition, the digital controller responsively causes the respective switch to switch to the off state to electrically isolate the power source and the load.

24. The digital current limiter of claim 23, wherein the over-current condition is caused by an overload condition, and wherein the digital controller responsively causes the respective switch to switch to the off state to electrically isolate the power source and the load in response to the overload condition.

25. The digital current limiter of claim 20, wherein when the digital controller determines that the magnitude of the current and an input voltage from the power source indicates an over-power condition, the digital controller responsively causes the respective switch to switch to the off state to electrically isolate the power source and the load.

26. The digital current limiter of claim 25, wherein the over-power condition is caused by an overload condition, and wherein the digital controller responsively causes the respective switch to switch to the off state to electrically isolate the power source and the load in response to the overload condition.

27. The digital current limiter of claim 20, wherein the digital controller includes a communication interface, the communication interface being serially connected to a master controller that controls a power switch electrically coupled to the load.

28. The digital current limiter of claim 27, wherein the master controller is capable of turning the power switch to the load on or off.

29. A method for controlling current flow, comprising:
determining a level of a given current flow on a circuit;
comparing the level of the given current flow to a first predetermined level;
(i) if the level of the current flow is greater than the first predetermined level,
incrementing a digital counter,
comparing the digital counter to a predefined counter value,
if the digital counter is equal to the predefined counter value, responsively interrupting the given current flow on the circuit, otherwise,
comparing the level of the given current flow to a second predetermined level,
if the level of the current flow is greater than the second predetermined level, responsively interrupting the given current flow on the circuit, otherwise,
returning to the step of determining the level of the given current flow on a circuit; and
(ii) if the level of the current flow is greater than the first predetermined level,
decrementing the digital counter,
determining if the digital counter is less than zero,
if the digital counter is less than zero, resetting the digital counter and advancing to the step of determining the level of the given current flow on a circuit the digital counter to a predefined counter value, otherwise,
returning to the step of determining the level of the given current flow on a circuit the predetermined counter value.

30. The method of claim 29, wherein the first predetermined level is an over-current limit level, and wherein the second predetermined level is a critical-current limit level.

31. The method of claim 29, wherein each of the first predetermined level, the second predetermined level, and the predefined counter value can be modified.

32. The method of claim 29, wherein interrupting the given current flow on the circuit includes turning off a switch.

33. A digital circuit breaker comprising a microprocessor executing the method of claim 29.

34. The digital circuit breaker of claim 33, wherein the microprocessor is capable of executing the method of claim 29 for each of multiple current flows on the circuit.

35. A method for limiting current to a plurality of circuits, comprising:
determining at a digital controller whether current through at least one of the plurality of circuits exceeds a predetermined threshold condition; and
upon determining that the threshold condition has been exceeded, pulsing a switch on and off to limit current to the at least one circuit.
